(19) United States
(12) Patent Application Publication
(10) Pub. No.: US 2026/0221385 A1
(43) Pub. Date: Jul. 30, 2026

(54) ION IMPLANTER

(71) Applicant: NISSIN ION EQUIPMENT CO., LTD., Koka-city (JP)

(72) Inventor: Sami K. HAHTO, Nashua, NH (US)

(73) Assignee: NISSIN ION EQUIPMENT CO., LTD., Koka-city (JP)

(21) Appl. No.: 19/312,547

(22) Filed: Aug. 28, 2025

Related U.S. Application Data
(60) Provisional application No. 63/751,449, filed on Jan. 30, 2025.

(51) Int. Cl. H01J 37/317; H01J 37/05

(52) U.S. Cl. CPC H01J 37/3171; H01J 37/05; H01J 2237/055; H01J 2237/057; H01J 2237/31705

(57) ABSTRACT

An ion implanter includes an ion source that extracts a ribbon beam, a mass analyzing electromagnet, a mass resolution slit, an accelerator/decelerator tube, an energy separation electromagnet, and a process chamber. The ribbon beam that is extracted passes through the mass analyzing electromagnet, the mass resolution slit, the accelerator/decelerator tube, and the energy separation electromagnet to the process chamber, and deflection directions of the ribbon beam by the mass analyzing electromagnet and the energy separation electromagnet are opposite to each other with respect to a traveling direction of the ribbon beam.

### CROSS-REFERENCE TO RELATED APPLICATION

This Application claimed the benefit of priority to U.S. Provisional Application No. 63/751,449 filed on Jan. 30, 2025, the contents of which being herein incorporated by reference in its entirety.

### BACKGROUND

### 1. Field

The present disclosure relates to a high current ion implanter.

### 2. Description of Related Art

Ion implanters used for manufacturing semiconductor devices can be classified into three types, i.e., a medium-current ion implanter, a high current ion implanter, and a high energy ion implanter, according to a beam current range and an energy range of an ion beam handled by ion implanters.

Although numerical values change depending on an ion species implanted into a semiconductor wafer, a commercially available high current ion implanter having a beam current in the neighborhood of ten mA and an energy range of several hundred eV to several tens keV is sold.

Since a structure of semiconductor devices is changing rapidly the more highly integrated the semiconductor device become, it is expected that the range of ion beam energies and beam currents that can be handled by a single implanter will be increased so that the single implanter may handle a wider range of processes.

### SUMMARY

According to an aspect of one or more embodiments, there is provided an ion implanter comprising an ion source that extracts a ribbon beam, a mass analyzing electromagnet, a mass resolution slit, an accelerator/decelerator tube, an energy separation electromagnet, and a process chamber. The ribbon beam that is extracted passes through the mass analyzing electromagnet, the mass resolution slit, the accelerator/decelerator tube, and the energy separation electromagnet to the process chamber, and deflection directions of the ribbon beam by the mass analyzing electromagnet and the energy separation electromagnet are opposite to each other with respect to a traveling direction of the ribbon beam.

According to another aspect of one or more embodiments, there is provided an ion implanter comprising an ion source that extracts a ribbon beam, a mass analyzing electromagnet, a mass resolution slit, a corrector array, an accelerator/decelerator tube, an energy separation electromagnet, a process chamber, and a controller that controls the ion source, the mass analyzing electromagnet, the mass resolution slit, the corrector array, the accelerator/decelerator tube, and the energy separation electromagnet. The ribbon beam that is extracted passes in a traveling direction through the mass analyzing electromagnet, the mass resolution slit, the corrector array, the accelerator/decelerator tube, and the energy separation electromagnet to the process chamber, the controller controls the corrector array to adjust a beam current density distribution in a length direction of the ribbon beam, and the controller controls the mass analyzing electromagnet and the energy separation electromagnet such that deflection directions of the ribbon beam by the mass analyzing electromagnet and the energy separation electromagnet are opposite to each other with respect to the traveling direction of the ribbon beam.

### BRIEF DESCRIPTION OF THE DRAWINGS

The above and/or other aspects will become apparent and more readily appreciated from the following description of various embodiments, taken in conjunction with the accompanying drawings, in which:

FIG. 1 illustrates an example of a ribbon beam;

FIG. 2 illustrates an example of an ion implanter, according to some embodiments;

FIG. 3 illustrates an example of a perspective view of a mass analyzing electromagnet, according to some embodiments;

FIG. 4 illustrates an example of a cross-section view of a mass analyzing electromagnet, according to some embodiments;

FIG. 5 illustrates an example of a corrector array, according to some embodiments;

FIGS. 6A and 6B illustrate an example of voltages applied to a corrector array, according to some embodiments;

FIG. 7 illustrates an example of an energy separation electromagnet, according to some embodiments; and

FIG. 8 illustrates an example of a beam shaping lens, according to some embodiments.

### DETAILED DESCRIPTION

Hereinafter, various embodiments of the present disclosure will be described with reference to the drawings. In all the drawings for explaining the various embodiments, common components are denoted by the same reference numerals, and repeated description thereof will be omitted for conciseness. The following embodiments do not unduly limit the contents of the present disclosure described in the appended claims. Further, all the components shown in the embodiments are not necessarily essential components of the present disclosure. Each drawing is a schematic view and is not necessarily intended to illustrate various dimensions strictly.

In a high current ion implanter, since a beam current of an ion beam irradiated to a wafer is increased, it is advantageous to use a ribbon-shaped beam (hereinafter, referred to as a ribbon beam) rather than using a spot-shaped ion beam that is scanned.

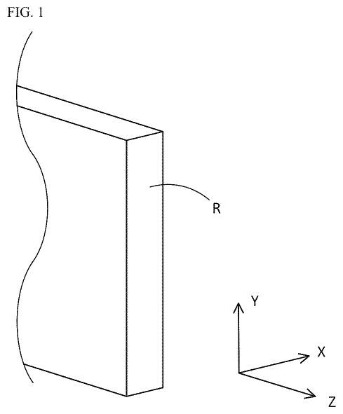

As illustrated in FIG. 1, a ribbon beam R has a substantial rectangular cross section when the ribbon beam R is cut along a plane (XY plane) perpendicular to a Z axis, the Z axis being a traveling direction of the ribbon beam R. In the cross-section of the ribbon beam R, a dimension in a Y-axis direction is longer than a dimension in a X-axis direction. For convenience, the Y-axis direction is referred to as a length of the ribbon beam R, and the X-axis direction is referred to as a width of the ribbon beam.

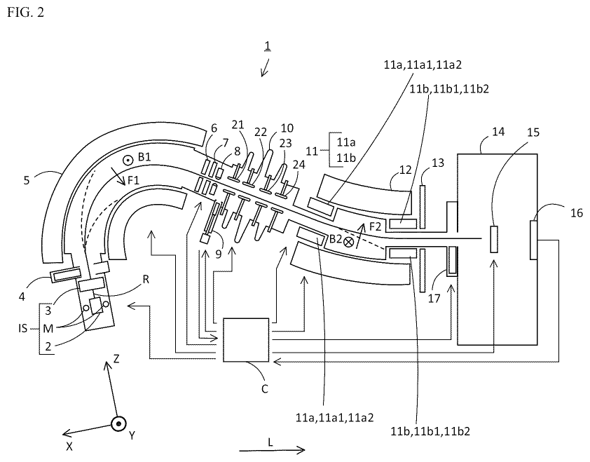

FIG. 2 shows an example of a configuration of a high current ion implanter 1. In an embodiment, the high current ion implanter 1 may include an ion source IS, a first gate valve 4, a mass analyzing electromagnet 5, a mass resolution slit 6, a shield 7, a corrector array 8, a flag Faraday 9, an acceleration/deceleration tube 10, a beam shaping lens 11, an energy separation electromagnet 12, and a magnetic shield 13, and a second gate valve 17. In some embodiments, the ion implanter 1 may include a controller C.

The ion source IS may be, for example, an indirectly heated ion source or a Bernas type ion source. The ion source IS includes a plasma chamber 2, a source magnet M, and extraction electrodes 3. In the plasma chamber 2, a plasma containing ion species used for manufacturing a semiconductor device is generated. The plasma may be generated by arc-discharging a raw material gas supplied to the plasma chamber 2 or a gas supplied from, for example, a gas bottle and/or a vaporizer externally attached to the plasma chamber 2, into the plasma chamber 2.

As the source magnet M, in some embodiments, a magnetic field source as described in U.S. patent application Ser. No. 13/835,441, filed Mar. 15, 2013, now U.S. Pat. No. 8,994,272 for “ION SOURCE HAVING AT LEAST ONE ELECTRON GUN COMPRISING A GAS INLET AND PLASMA REGION DEFINED BY AN ANODE AND A GROUND ELEMENT THEREOF”, the entire contents of which being herein incorporated by reference, may be used.

In an embodiment, the source magnet M may have a pair of magnetic cores extending along a direction normal to the surface of the paper of FIG. 2. In other words, there may be one magnetic core on each side of the plasma chamber 2 as illustrated in FIG. 2. Three coils are wound around each core. By controlling both a current direction and current amount in each coil independently, a desired magnetic field parallel to an extending direction of the cores may be generated in the plasma chamber 2.

A ribbon beam R having a certain energy is extracted from the plasma generated in the plasma chamber 2 to a beamline by a potential difference between the plasma chamber 2 and the extraction electrodes 3. In FIG. 2, a length direction of the ribbon beam R extracted from the ion source IS is a direction normal to the paper of FIG. 2. In an embodiment, a size of the ribbon beam R in the length direction thereof may be about 200 mm to about 300 mm.

As used in this specification, the term “beamline” refers to a transport path of the ribbon beam R surrounded by a vacuum chamber from the ion source IS to a process chamber 14.

The extraction electrodes 3 include two to four electrodes having an opening through which the ribbon beam R passes. The opening of each electrode may be formed of a plurality of slits, a single slit, multiple holes or a single hole.

The first gate valve 4 is provided downstream of the extraction electrodes 3. During ion implantation, the first gate valve 4 is opened to allow the ribbon beam R to be transported to the beamline. When the ion source IS is maintained (e.g., maintenance is performed, etc.), the first gate valve 4 closes the beamline to spatially separate the ion source IS from the beamline.

The mass analyzing electromagnet 5 is disposed downstream of the first gate valve 4. The mass analyzing electromagnet 5 has a space therein through which the ribbon beam R passes. In an embodiment, in the length direction of the ribbon beam R, a size of the space may be about 500 mm.

The mass analyzing electromagnet 5 selects a desired ion species from various ion species included in the ribbon beam R extracted from the ion source IS in cooperation with the mass resolution slit 6 disposed on the downstream side of the mass analyzing electromagnet 5 according to a difference in mass of the ion species passing through the mass analyzing electromagnet 5. Therefore, only the ribbon beam R containing the desired ion species is transported to the downstream side of the mass resolution slit 6.

As described above, as the ion source IS, in some embodiments, the vaporizer may be used. For example, the vaporizer may generate a gas containing aluminum from an aluminum solid material by using a chloride gas in a vaporizer as described in U.S. patent application Ser. No. 17/714,491, filed Apr. 6, 2022, now U.S. Pat. No. 12,112,915 for “VAPORIZER, ION SOURCE AND METHOD FOR GENERATING ALUMINUM-CONTAINING VAPOR” and/or U.S. patent application Ser. No. 17/945,705, filed Sep. 15, 2022, now U.S. Patent Application Publication No. 2024/098869 for “VAPORIZER, ION SOURCE AND METHOD FOR GENERATING ALUMINUM-CONTAINING VAPOR”, the entire contents of each of these U.S. patent applications being herein incorporated by reference in their entireties.

The ion source IS converts the gas into plasma and then extracts the ion beam. The ribbon beam R from the ion source IS contains positively charged aluminum ions as well as other ion species such as chloride ions and hydrogen chloride ions.

The production of P-type devices in SiC wafers requires an implantation of aluminum ions. In this case, a magnetic field of the mass analyzing electromagnet 5 may be adjusted so that a trajectory of the ribbon beam R containing aluminum ions is the trajectory drawn by the solid line in FIG. 2.

For example, the trajectory depicted by the solid line has a bend radius of approximately 500 mm and a deflection angle of approximately 120 degrees. The deflection angle referred to here is the angle formed by an entrance and an exit of a vacuum chamber disposed inside the mass analyzing electromagnet 5, and when looking only at the electromagnet portion, the bend angle is approximately 95 degrees.

Embodiments are not limited to aluminum ions. For example, the ion species handled by the ion implanter 1 is not limited to aluminum ions, and in some embodiments, the ion implanter 1 may handle other ion species such as boron, phosphorus, hydrogen, and/or nitrogen, for example.

The acceleration/deceleration tube 10 may comprise a first electrode 21, a second electrode 22, a third electrode 23 and a fourth electrode 24. A difference of voltage potential between the first electrode 21 and the fourth electrode 24 may determine an energy of the ribbon beam R passing through the acceleration/deceleration tube 10. Voltage potentials of the second electrode 22 and the third electrode 23 may determine optical specifications of the ribbon beam R like a beam width and a beam length. While four electrodes are illustrated in FIG. 2, this is only an example and, in some embodiments, the acceleration/deceleration tube 10 may include a greater number or a fewer number of electrodes.

Each electrode includes a pair of electrodes facing each other across the ribbon beam R. In an embodiment, each electrode may include two electrodes that face each other across the ribbon beam R. In some embodiments, each electrode may be provided as a single electrode with an open hole through which the ribbon beam R passes.

The divergence of the ribbon beam R due to the space charge effect depends on the ion beam energy of the ribbon beam R. When the ribbon beam R is decelerated by the acceleration/deceleration tube 10, the ribbon beam R may diverge significantly. If the ribbon beam R diverges, a portion of the ribbon beam R may strike structures such as the first to fourth electrodes 21-24 inside the acceleration/deceleration tube 10 or the entrance of the energy separation electromagnet 12. As a result, the amount of the ribbon beam R transported to the process chamber 14 may decrease.

In response to the energy of the ribbon beam R, the voltage potentials of the second electrode 22 and/or the third electrode 23 may be adjusted to increase the amount of the ribbon beam R transported to the process chamber 14. For example, in an embodiment, the voltage potential of the second electrode 22 may be set by a bias power supply connected between the first electrode 21 and the second electrode 22. In some embodiments, the polarity of the bias power supply may be inverted depending on the energy of the ribbon beam R. In some embodiments, the voltage potentials of the second electrode 22 and the third electrode 23 may be independently adjusted.

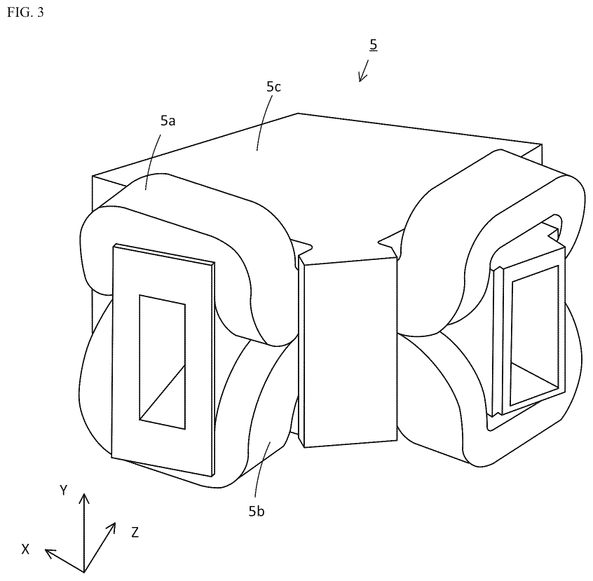

The mass analyzing electromagnet 5 generates a magnetic field B1 from the rear side to the front side of the paper surface of FIG. 2. The ribbon beam R having positive charges passing through the mass analyzing electromagnet 5 is subjected to a Lorentz force F1 by the magnetic field B1 of the mass analyzing electromagnet 5 so that the traveling direction of the ribbon beam R is deflected to the right (e.g., in the −X-axis direction in FIG. 3).

FIG. 3 shows a perspective view of the mass analyzing electromagnet 5, according to some embodiments. In an embodiment, the mass analyzing electromagnet 5 may include a plurality of saddle coils. For example, in an embodiment, the mass analyzing electromagnet 5 may include an upper saddle coil 5a and a lower saddle coil 5b. The upper saddle coil 5a and the lower saddle coil 5b generate the magnetic field B1 inside of a yoke portion 5c of the mass analyzing electromagnet 5. In some embodiments, the upper saddle coil 5a may be formed of a plurality of coils stacked together. Similarly, in some embodiments, the lower saddle coil 5b may be formed of a plurality of coils stacked together. At the entrance region of the mass analyzing electromagnet 5, a portion of the upper saddle coil 5a extends outside of the yoke portion 5c. Similarly, at the exit region of the mass analyzing electromagnet 5, a portion of the lower saddled coil 5b extends outside of the yoke portion 5c.

The XYZ axes depicted in FIG. 3 correspond to the axes depicted in FIG. 2 for the ribbon beam R and illustrate the axial arrangement of the ribbon beam R entering the mass analyzing electromagnet 5. When the ribbon beam R with a large longitudinal dimension in the length direction of the ribbon beam R passes through the mass analyzing electromagnet 5, the Y-axis dimension of the mass analyzing electromagnet 5 is enlarged to accommodate the ribbon beam R and, as the Y-axis dimension is enlarged, the dimensions of the upper and lower saddle coils 5a, 5b are also enlarged. The expansion of the dimensions of the upper and lower saddle coils 5a, 5b also increase the dimensions of the portions of the upper and lower saddle coils 5a, 5b that extend outward from the yoke portion 5c of the mass analyzing electromagnet 5.

The larger the dimension of the portions of the upper and lower saddle coils 5a, 5b that extend outside of the yoke portion 5c, the more strongly the fringe magnetic field generated by the portions of the upper and lower saddle coils 5a, 5b that extend outside of the yoke portion 5c become. Before reaching the yoke portion 5c of the mass analyzing electromagnet 5, the fringe magnetic field causes the Lorentz force to act on the ribbon beam R in a right direction (e.g., a −X axis direction) relative to the traveling direction of the ribbon beam R. Similarly, after passing the yoke portion 5c of the mass analyzing electromagnet 5, the Lorentz force to act on the ribbon beam R in the right direction relative to the traveling direction of the ribbon beam R.

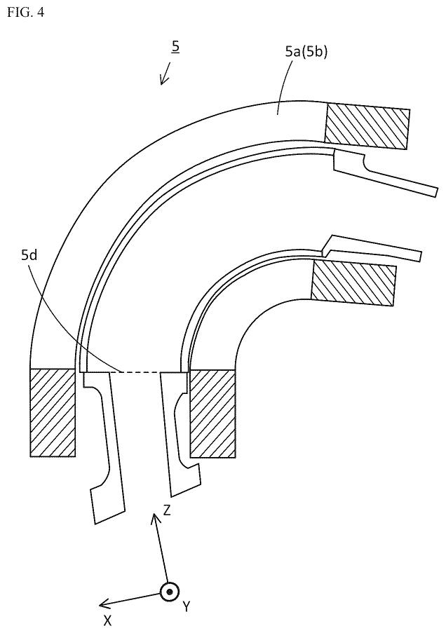

In consideration of such fringe magnetic field of the mass analyzing electromagnet 5, vacuum chambers of the beamline are obliquely connected to the inlet and the outlet portion of the mass analyzing electromagnet 5 as shown in FIG. 4.

FIG. 4 shows cross-section of the mass analyzing electromagnet 5 in ZX plane, according to some embodiments. In FIG. 4, hatching areas of the upper and lower saddle coils 5a, 5b are the portions that extend outside of the yoke portion 5c of the mass analyzing electromagnet 5.

As shown in FIG. 4, by making the ribbon beam R obliquely incident on an inlet portion 5d of the mass analyzing electromagnet 5 in the ZX plane, the dimensions of a mass analyzer including the mass analyzing electromagnet 5 and the mass resolution slit 6 in an L direction shown in FIG. 2 can be made compact, compared to when the ribbon beam R is incident perpendicularly to the inlet portion 5d of the mass analyzing electromagnet 5 or when the ribbon beam R is incident obliquely on the inlet 5d of the mass analyzing electromagnet 5, including a component directed toward the process chamber 14.

As a result, the dimension of the ion implanter 1 in the L direction may be made compact. In some embodiments, instead of making the dimensions of the ion implanter 1 compact in the L direction, other optical elements and/or a vacuum pump may be arranged downstream of the mass resolution slit 6 to accommodate the reduced dimensions of the mass analyzer.

The oblique injection and extraction of the ribbon beam R with respect to the mass analyzing electromagnet 5 is to be able to utilize a large fringe magnetic field to deflect the ribbon beam R as large an angle as possible. A larger bend angle means a higher mass resolution. By utilizing these fringe magnetic fields, a high mass resolution can be achieved with a compact analyzing magnet.

In FIG. 2, desired ion species are shown by the solid line, and the ion species having a lighter mass and a heavier mass are shown by respective broken lines on either side of the solid line. As illustrated in FIG. 2, when the ion species pass through the mass analyzing electromagnet 5, the ion species having the lighter mass are deflected more greatly than the desired ion species, and collide with the inner wall of the mass analyzing electromagnet 5. On the contrary, the ion species having the heavier mass are deflected by a smaller amount than the desired ion species, and collides with the outer inner wall of the mass analyzing electromagnet 5.

In an embodiment, the inner wall of the mass analyzing electromagnet 5 may be covered with a carbon liner (not shown) in order to avoid contamination or sputtering of the inner wall of the mass analyzing electromagnet 5 when an undesired ion species collides with the inner wall.

The mass resolution slit 6 is formed of a plate having a slit with an opening width of a dimension in the width direction of the ribbon beam R. The dimension may be predetermined. The opening width may be fixed or variable. For example, in an embodiment, the mass resolution slit 6 may include two plates separated into the right side and the left side in the traveling direction of the ribbon beam R, and each plate may configured to rotate about a rotation axis in a direction parallel to the length direction of the ribbon beam R, thereby making the opening width of the slit variable.

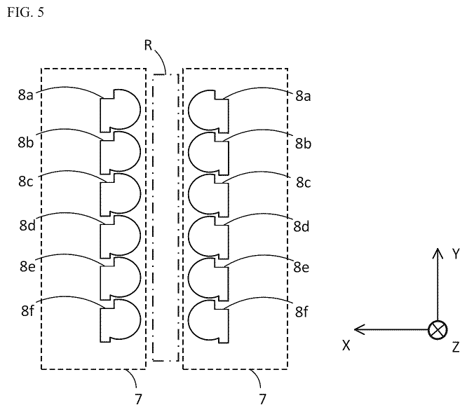

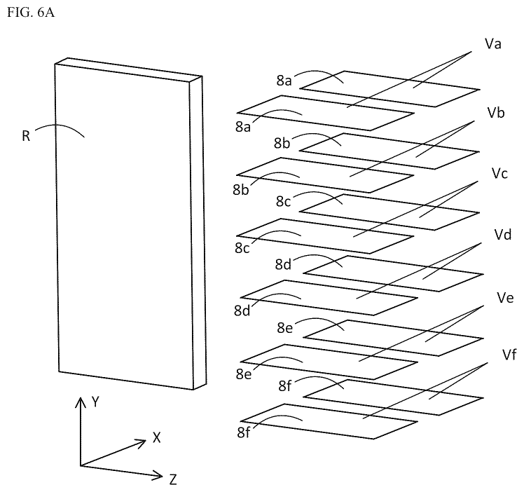

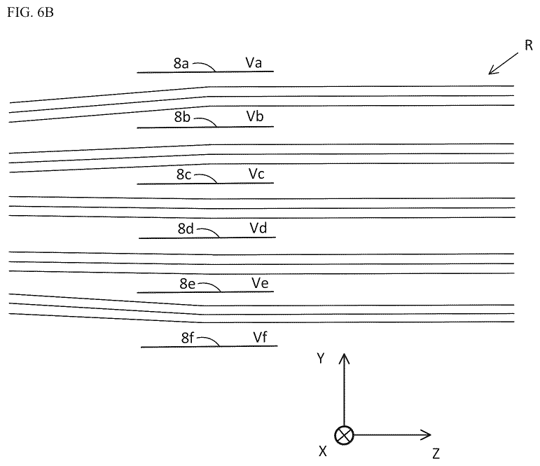

FIG. 5 illustrates an example of a corrector array, according to some embodiments. FIGS. 6A and 6B illustrate an example of voltages applied to a corrector array, according to some embodiments. The corrector array 8 is disposed downstream of the mass resolution slit 6. As shown in FIG. 5, in an embodiment, the corrector array 8 may be configured by a group of electrodes in which pairs of electrodes 8a-8f facing each other in the width direction of the ribbon beam R are arranged in the length direction of the ribbon beam R. The number of electrodes shown in FIG. 5 is only an example by way of illustrated and, in some embodiments, the number of electrodes arranged in the length direction of the ribbon beam R may be three or more.

In an embodiment, the corrector array 8 may be implemented as a beam current density distribution adjustment device as described in U.S. patent application Ser. No. 15/162,929, filed May 24, 2016, now U.S. Pat. No. 9,734,982 titled “BEAM CURRENT DENSITY DISTRIBUTION ADJUSTMENT DEVICE AND ION IMPLANTER”, the entire contents of which being herein incorporated by reference in its entirety.

A voltage of the same value is applied to the pair of electrodes opposed to each other in the width direction of the ribbon beam R. For example, a same voltage may be applied to each electrode of the pair of electrodes 8a, a same voltage may be applied to each electrode of the pair of electrodes 8b, and so on. That is, Va may be applied to the right hand electrode 8a and Va may be applied to the left hand electrode 8a, and Vb may be applied to the right hand electrode 8b and Vb may be applied to the left hand electrode 8b, as so on, as shown in FIGS. 6A and 6B. In an embodiment, the same voltage may be applied to each pair of electrodes 8a to 8f. For example, in FIGS. 6A and 6B, in some embodiments, the voltages may satisfy Va=Vb=Vc=Vd=Ve=Vf. In an embodiment, the voltage applied to one pair of electrodes 8a to 8f may be different than the voltage applied to another pair of electrodes 8a to 8f. For example, in FIGS. 6A and 6B, in some embodiments, each voltage Va, Vb, Vc, Vd, Ve, and Vf may be different, or at least one of the voltages Va, Vb, Vc, Vd, Ve, and Vf may be different from the others. In some embodiments (not shown), a voltage V1 may be applied to the right hand electrode 8a and the voltage V1 may be applied to the left hand electrode 8a, and a voltage V2 may be applied to the right hand electrode 8b and the voltage V2 may be applied to the left hand electrode 8b, where V2 is different from V1. By changing the voltage applied to the pairs of the electrodes arranged in the length direction of the ribbon beam R, an electric field is locally generated in the length direction of the ribbon beam R. By generating the local electric field, the ribbon beam R is partially deflected in the length direction of the ribbon beam R. This deflection occurs partially in the length direction of the ribbon beam R in the upper and lower direction in FIG. 5. Thus, the profile of the beam current density distribution in the length direction of the ribbon beam R may be adjusted.

In each pair of electrodes 8a-8f constituting the corrector array 8, the surface on the side facing the ribbon beam R has a rounded shape and does not have a corner portion (e.g., a right angle corner). If the electrodes 8a-8f have a corner portion a sharp local focusing effect of the ribbon beam R traveling close to the electrodes 8a-8f in the width direction of the ribbon beam R may be induced. Thus, the corner portion may cause a problem of skewing the beam shape in transporting the ribbon beam R. However, such a concern can be addressed by the rounded shape of electrodes of the corrector array 8.

In an embodiment, the shape of the electrodes 8a-8f of the corrector array 8 may be flat (e.g., not rounded) if the ribbon beam R is much narrower than a separation between a left side element of the corrector array 8 and a right side element of the collector array 8. This shape is because a field non-linearity due to the lack of the rounded surface is localized fairly close to the left side elements and the right side elements.

As illustrated in FIG. 2, the shield 7 is disposed between the corrector array 8 and the mass resolution slit 6. The shield 7 prevents the ribbon beam R that has passed through the mass resolution slit 6 from being irradiated on the corrector array 8. When the ribbon beam R is irradiated to the corrector array 8, the corrector array 8 is sputtered and the corrector array 8 is consumed. Further, contamination derived from the ion species desired in a previous process adheres to the corrector array 8. When the ion species is different from the ion species desired in a subsequent process, contamination of the ion species may occur. The arrangement of the shield 7 can eliminate such a concern. Further, since the ribbon beam R is irradiated to the shield 7, it is considered that the shield 7 is sputtered and the components constituting the shield 7 are scattered to the downstream side. When a process which is not desired to be contaminated with metal is handled, the shield 7 may be made of a nonmetallic carbon member.

In some embodiments, instead of providing the shield 7, the mass resolution slit 6 may be placed close to the corrector array 8 and used in place of the shield 7 to block the irradiation from the corrector array 8 by the ribbon beam R. For example, in an embodiment, the mass resolution slit 6 may be placed adjacent to the corrector array 8 such that the ribbon beam R may not be irradiated onto the corrector array 8. In this case, the shield 7 may be omitted from the beamline.

The shield 7 may be made of a ferromagnetic material, such as iron, nickel or cobalt to work as a magnetic shield for a fringe magnetic field of the mass analyzing electromagnet 5.

The flag Faraday 9 is disposed downstream of the corrector array 8. The flag Faraday 9 has a structure in which a single Faraday cup is attached to a tip of a driving shaft and can be inserted into and removed from a transport path of the ribbon beam R. When an operation of the ion source IS is started, the flag Faraday 9 is moved into the transport path of the ribbon beam R, and the beam current amount of the ribbon beam R is measured. A beam measurement region of the flag Faraday 9 is long in the length direction of the ribbon beam R, and the beam current of the ribbon beam R passing through the corrector array 8 can be measured. The flag Faraday 9 is moved to the outside of the transport path of the ribbon beam R and is disposed at a position where the flag Faraday 9 does not hinder the transport of the ribbon beam R in the ion implantation process.

In some embodiments, the flag Faraday 9 may have a suppression electrode to enclose secondary electrons generated into the single Faraday cup. In some embodiments, if the flag Faraday 9 does not have the suppression electrode, the corrector array 8 immediately before the flag Faraday 9 may function as the suppression electrode. In this case, when the flag Faraday 9 is used to measure the beam current of the ribbon beam R, an electric potential of the corrector array 8 is set to an electric potential of the suppression electrode relative to the flag Faraday 9. For example, in some embodiments, the electric potential may be negative and may be several hundred voltages. If beam current measurement by the flag Faraday 9 is performed, the electric potential of the corrector array 8 is lower than the electric potential of the flag Faraday 9.

If the collector array 8 also serves as a suppression electrode, a potential of the collector array 8 may be set to a constant electric potential at all times, regardless of the measurement by the flag Faraday 9. In some embodiments, a circuit for switching the electric potential setting may be provided and the electric potential of collector array 8 may be switched depending on whether flag Faraday 9 is used or not.

The acceleration/deceleration tube 10 is disposed downstream of the flag Faraday 9. The ribbon beam R has energy corresponding to the extraction voltage when extracted by the extraction electrode 3. The acceleration/deceleration tube 10 converts the energy of the ribbon beam R into desired energy. In an embodiment, the accelerating/decelerating tube 10 may include four independent electrodes. Each electrode has a space through which the ribbon beam R passes. A potential of the electrode positioned on the most downstream side is set to a ground potential, and the energy of the ribbon beam R passing through the electrode is converted by adjusting the voltage applied to the other electrodes. The energy conversion has three modes of acceleration, deceleration, and drift according to the voltage applied to each electrode.

In the acceleration mode, the ribbon beam R passes through the acceleration/deceleration tube 10 and the energy of the ribbon beam R is increased by the acceleration/deceleration tube 10. In the deceleration mode, the ribbon beam R passes through the acceleration/deceleration tube 10 and the energy of the ribbon beam R is decreased by the acceleration/deceleration tube 10. In the drift mode, the ribbon beam R passes through the acceleration/deceleration tube 10 and the energy of the ribbon beam R is not changed. By providing such an acceleration/deceleration tube 10, it is possible to handle the ribbon beam R having a wide range of energy from several hundred eV to several hundred keV.

The energy separation electromagnet 12 is disposed downstream of the accelerating/decelerating tube 10. The energy separation electromagnet 12 deflects the ribbon beam R according to the charge of a particle passing therethrough, thereby separating a neutral particle from the ribbon beam R and preventing energy contamination. The neutral particles are generated by being converted into neutral particles by charge conversion due to collision with a residual gas in the acceleration/deceleration tube 10 when the ribbon beam R passes through the acceleration/deceleration tube 10. The dashed line in the energy separation electromagnet 12 in FIG. 2 represents a trajectory of neutral particles. A deflection angle of the energy separation electromagnet 12 is about 20 degrees, and the bend radius is about 1000 mm.

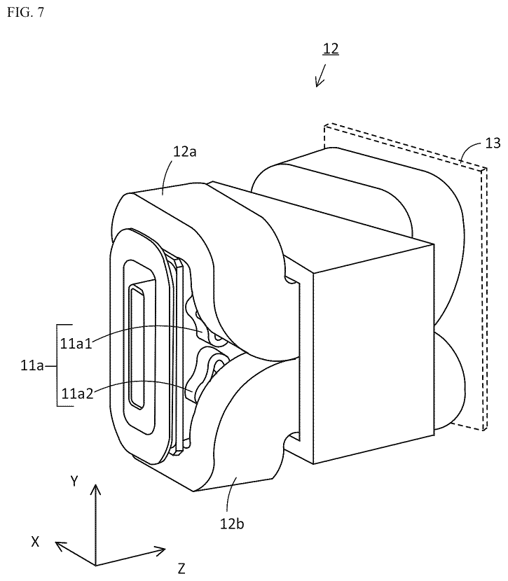

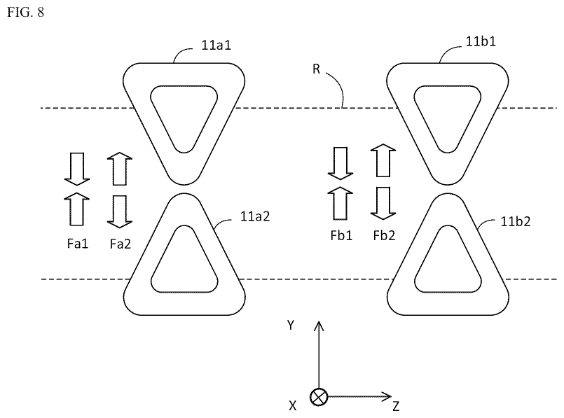

FIG. 7 is a perspective view of the energy separation electromagnet 12, according to some embodiments. FIG. 8 illustrates an example of beam shaping lens, according to some embodiments. As shown in FIG. 7, the energy separation electromagnet 12 may include a plurality of saddle coils. For example, in some embodiments, the energy separation electromagnet 12 may include an upper saddle coil 12a and a lower saddle coil 12b. When a current is applied to the upper and lower saddle coils 12a and 12b, a magnetic field B2 is generated from the upper saddle coil 12a to the lower saddle coil 12b in FIG. 7. As shown in FIG. 2, by the magnetic field B2, a Lorentz force F2 acts on the ribbon beam R passing through the energy separation electromagnet 12 so that the traveling direction of the ribbon beam R is deflected to the left side (e.g., in a +X-axis direction in FIG. 7).

The mass analyzing electromagnet 5 and the energy separation electromagnet 12 are in a relationship in which the deflection directions of the ribbon beam R are opposite. Since the deflection directions of the mass analyzing electromagnet 5 and the energy separation electromagnet 12 are reversed and the ribbon beam R is bent back by the energy separation electromagnet 12, in the configuration of the ion implanter 1 shown in FIG. 2, the apparatus dimension in the ZX plane of the FIG. 2 can be reduced. It is noted that the Z axis in FIG. 2 is the traveling direction of the ribbon beam R, and thus the X and Y axis directions change from those illustrated in FIG. 2 depending upon a position of the ribbon beam R along the beamline. Thus, the ion implanter 1 can be disposed in a smaller space.

The beam shaping lens 11 for focusing, diverging, and collimating the ribbon beam R is disposed on an entrance side and an exit side of the energy separation electromagnet 12. In FIG. 2, two lenses, that is, a first beam shaping lens 11a disposed on the entrance side and a second beam shaping lens 11b disposed on the exit side are provided. However, this configuration is only an example and, in some embodiments, only one of the first beam shaping lens 11a or the second beam shaping lens 11b may be provided.

The first beam shaping lens 11a and the second beam shaping lens 11b are disposed outside a vacuum chamber constituting the internal passage of the energy separation electromagnet 12. The first beam shaping lens 11a may include a plurality of coils. For example, in an embodiment, the first beam shaping lens 11a may include two upper coils 11a1 arranged to sandwich the ribbon beam R in the width direction of the ribbon beam R (it is noted that only one of the two upper coils 11a1 is illustrated in FIG. 7 due to the perspective view) and two lower coils 11a2 arranged to sandwich the ribbon beam R in the width direction of the ribbon beam R (similarly, only one of the two lower coils 11a2 is illustrated in FIG. 7 due to the perspective view). The second beam shaping lens 11b is also configured in the same manner with the first beam shaping lens 11a. That is, the second beam shaping lens 11b may include a plurality of coils. For example, in an embodiment, the second beam shaping lens 11b may include two upper coils 11b1 arranged to sandwich the ribbon beam R in the width direction of the ribbon beam R and a lower coil 11b2 arranged to sandwich the ribbon beam R in the width direction of the ribbon beam R.

In FIG. 8, an amount of current flowing through the two upper coils 11a1 is made equal and an amount of current flowing through the two lower coils 11a2 is made equal, and a magnetic field generated by the two upper coils 11a1 is in an opposite direction to a magnetic field generated by the two lower coils 11a2, whereby the ribbon beam R passing therethrough can be uniformly converged (Fa1) or diverged (Fa2) in the length direction of the ribbon beam R.

Similarly, an amount of current flowing through the two upper coils 11b1 is made equal and an amount of current flowing through the two lower coils 11b2 is made equal, and a magnetic field generated by the two upper coils 11b1 is in an opposite direction to a magnetic field generated by the two lower coils 11b2, whereby the ribbon beam R passing therethrough can be uniformly converged (Fb1) or diverged (Fb2) in the length direction of the ribbon beam R.

For example, by diverging the ribbon beam R by the first beam shaping lens 11a and then converging the ribbon beam by the second beam shaping lens 11b, the ribbon beam R passing through the energy separation electromagnet 12 can be transported to the process chamber 14 on the downstream side as a collimated beam by increasing the size in the length direction of the ribbon beam R.

On the contrary, by converging the ribbon beam R by the first beam shaping lens 11a and then diverging the ribbon beam by the second beam shaping lens 11b, the ribbon beam R passing through the energy separation electromagnet 12 can be transported to the process chamber 14 on the downstream side as a collimated beam by reducing the size in the longitudinal direction.

However, a method of using the beam shaping lens 11 is not limited to the above-described method. Deflection amounts of the first beam shaping lens 11a and the second beam shaping lens 11b may be made different from each other so that the ribbon beam R has angular components in the length direction of the ribbon beam R.

Further, an intensity of the magnetic field may be made different between the two upper coils 11a1 and the two lower coils 11a2 to deflect the ribbon beam R in an unbalanced manner in the length direction of the ribbon beam R.

The process chamber 14 is disposed on the downstream side of the energy separation electromagnet 12. A neutralizer (not shown) is disposed in a vicinity of the process chamber 14 or in the process chamber 14. A disadvantage may occur in that a fringe magnetic field of the energy separation electromagnet 12 acts on the electrons for neutralization emitted from the neutralizer. Further, a disadvantage may occur in that the trajectory of the ribbon beam R after passing through the energy separation electromagnet 12 is affected.

As a countermeasure against these disadvantages, the magnetic shield 13 is disposed on the downstream side of the energy separation electromagnet 12. For example, in an embodiment, the magnetic shield 13 may be disposed just downstream of the energy separation electromagnet 12. By disposing the magnetic shield 13, the adverse effect of the fringe magnetic field of the energy separation electromagnet 12 is eliminated.

In some embodiment, an additional magnetic shield may be disposed just upstream of the energy separation electromagnet 12 to eliminate the adverse effects of the fringe magnetic field upstream of the energy separation electromagnet 12. In an embodiment, the additional magnetic shield may be, for example, similar to the shield 7 and/or the magnetic shield 13, and thus a repeated description thereof is omitted for conciseness. The additional magnetic shield and the shield 7 allow the ribbon beam R to be straightly transported into the acceleration/deceleration tube 10.

However, in the case of the ion implanter 1 described in FIG. 2, the ribbon beam R can be straightly transported into the acceleration/deceleration tube 10 without the additional magnetic shield and the shield 7. In FIG. 2, the adverse effects of the fringe magnetic field of the mass analyzing electromagnet 5 may be canceled out by the adverse effects of the fringe magnetic field of the energy separation electromagnet 12, because the direction of the magnetic field B1 in the mass analyzing electromagnet 5 is opposite to the direction of the magnetic field B2 in the energy separation electromagnet 12.

The effect of the fringe magnetic field at each magnet does not have to be completely canceled. Complete cancellation is not required as long as the fringe magnetic field does not interfere with the ribbon beam R passing through the inside of a linear acceleration/deceleration tube 10.

In some embodiments, the ion implanter 1 in FIG. 2 may have no magnetic shields between the mass analyzing electromagnet 5 and the energy separation electromagnet 12. In other words, in some embodiments, the magnetic shields between the mass analyzing electromagnet 5 and the energy separation electromagnet 12 may be omitted from the ion implanter 1 in FIG. 2. This configuration provides several advantages: the length of the beamline can be shorter, and there is more available space to accommodate other optical elements, compared to an ion implanter that has magnetic shields between the mass analyzing electromagnet 5 and the energy separation electromagnet 12. This configuration with the magnetic shields omitted allows as compact of a geometry while still allowing the use of a linear acceleration/deceleration tube 10 because the over-bending of the beam by the exit fringe magnetic field of the mass analyzing electromagnet 5 is canceled by the over-bending of the beam by the inlet fringe magnetic field of the energy separation electromagnet 12. The second gate valve 17 is provided at an inlet of the process chamber 14. The second gate valve 17 closes the beamline to spatially separate the process chamber 14 from the beamline when a maintenance of an inside of the process chamber 14 is performed or when the transport of the ribbon beam R to the process chamber 14 is stopped.

A wafer 15 supported by a platen (not shown) is disposed in the process chamber 14. The dimension of the ribbon beam R in the length direction is longer than the dimension of the wafer 15 in the same direction. The dimension of the ribbon beam R in the width direction is shorter than the dimension of the wafer 15 in the same direction. When ions are implanted into the wafer 15, the wafer 15 is reciprocated across the ribbon beam R in the upper and lower directions in FIG. 2. Thus, the ion implantation process is performed on the wafer 15.

A profiler 16 is disposed in the process chamber 14. The profiler 16 may include a beam current measurement device in which a plurality of Faraday cups are arranged in the longitudinal direction of the ribbon beam R.

The result of the beam current density distribution measured by the profiler 16 is fed back to the corrector array 8, and the potential differences between the pairs of electrodes 8a-8f constituting the corrector array 8 is adjusted. Also, the result of the beam current measured by the flag Faraday 9 is fed back to the ion source IS and/or the mass analyzing electromagnet 5.

Abovementioned feedback controls are performed by the controller C in FIG. 2. The controller may include a processor and a memory. The processor may be a microprocessor, a central processing unit (CPU), a microcontroller, or hardware control logic, or some combination thereof. In some embodiments, the processor may be provided as a plurality of processors. In some embodiments, the controller C may be hardware control logic configured to set and/or control the electric potentials of the ion source IS, the corrector array 8, and the acceleration/deceleration tube 10, to set and/or control the current values of the mass analyzing electromagnet 5, the energy separation electromagnet 12, and the beam shaping lens 11, to control an open/close of the first gate valve 4 and an open/close the second gate valve 17, and/or to move the wafer 15 for ion implantation. While one controller C is illustrated and described as performing these functions, in some embodiments multiple portions of processors of the controller C may perform different functions or multiple controllers C may be provided, each performing a separate function.

Instead of the profiler 16, a moving faraday can be used to measure a beam current density profile in the length direction of the ribbon beam R. For example, the moving faraday has single faraday cup or multiple faraday cups aligned in the width direction of the ribbon beam R. In this configuration, the controller C moves the moving faraday along the length of ribbon beam R to measure the beam current density profile of the ribbon beam R.

It should be understood that embodiments are not limited to the various embodiments described above, but various other changes and modifications may be made therein without departing from the spirit and scope thereof as set forth in appended claims.

What is claimed is:

1. An ion implanter comprising:
an ion source that extracts a ribbon beam;
a mass analyzing electromagnet;
a mass resolution slit;
an accelerator/decelerator tube;
an energy separation electromagnet; and
a process chamber,
wherein the ribbon beam that is extracted passes through the mass analyzing electromagnet, the mass resolution slit, the accelerator/decelerator tube, and the energy separation electromagnet to the process chamber, and
wherein deflection directions of the ribbon beam by the mass analyzing electromagnet and the energy separation electromagnet are opposite to each other with respect to a traveling direction of the ribbon beam.

2. The ion implanter as recited in claim 1, wherein a fringe magnetic field of the mass analyzing electromagnet is canceled out by a fringe magnetic field of the energy separation electromagnet.

3. The ion implanter as recited in claim 1, further comprising a corrector array between the acceleration/deceleration tube and the mass resolution slit in a transport path of the ribbon beam, the corrector array being configured to adjust a beam current density distribution in a length direction of the ribbon beam.

4. The ion implanter as claimed in claim 3, wherein the corrector array comprises a plurality of pairs of electrodes that are arranged along the length direction of the ribbon beam,
wherein each pair of electrodes faces each other with the ribbon beam interposed therebetween, and
wherein a surface of each electrode that faces the ribbon beam is curved.

5. The ion implanter as recited in claim 3, further comprising a shield that blocks irradiation of the corrector array by the ribbon beam.

6. The ion implanter as recited in claim 3, wherein the mass resolution slit blocks irradiation of the corrector array by the ribbon beam.

7. The ion implanter as recited in claim 3, further comprising a flag faraday between the corrector array and the acceleration/deceleration tube, the flag faraday being configured to move into and out of the transport path of the ribbon beam to measure a beam current of the ribbon beam;
wherein an electric potential of the corrector array is lower than an electric potential of the flag faraday when a beam current measurement by the flag faraday is performed.

8. The ion implanter as claimed in claim 1, wherein a deflection angle of the ribbon beam deflected by the mass analyzing electromagnet is larger than a deflection angle of the ribbon beam deflected by the energy separation electromagnet.

9. The ion implanter as claimed to claim 1, wherein a bend radius of the ribbon beam bent by the mass analyzing electromagnet is smaller than a bend radius of the ribbon beam bent by the energy separation electromagnet.

10. The ion implanter as recited in claim 1, wherein the ribbon beam is incident obliquely to an inlet portion of the mass analyzing electromagnet.

11. The ion implanter as recited in claim 1, further comprising a corrector array between the acceleration/deceleration tube and the mass resolution slit, and a controller,
wherein the controller controls the corrector array to adjust a beam current density distribution in a length direction of the ribbon beam.

12. The ion implanter as claimed in claim 11, wherein the corrector array comprises a plurality of electrodes that are arranged on opposite sides of the corrector array along the length direction of the ribbon beam,
wherein a number of electrodes on a first side of the corrector array is the same as a number of electrodes on a second side of the corrector array such that the plurality of electrodes form a plurality of pairs of electrodes facing each other with the ribbon beam passing between the plurality of pairs of electrodes, and
wherein a surface of each electrode on the first side that faces the second side is curved, and a surface of each electrode on the second side that faces the first side is curved.

13. The ion implanter as recited in claim 11, wherein the mass resolution slit is disposed adjacent to the corrector array such that the ribbon beam is not irradiated onto the corrector array.

14. The ion implanter as recited in claim 11, further comprising a flag faraday between the corrector array and the acceleration/deceleration tube,
wherein the controller controls the flag faraday to move into and out of a transport path of the ribbon beam to measure a beam current of the ribbon beam, and
wherein the controller controls the corrector array and the flag faraday such that an electric potential of the corrector array is lower than an electric potential of the flag faraday when a beam current measurement by the flag faraday is performed.

15. The ion implanter as claimed in claim 11, wherein the controller controls the mass analyzing electromagnet to deflect the ribbon beam and the energy separation electromagnet to deflect the ribbon beam such that a deflection angle of the ribbon beam deflected by the mass analyzing electromagnet is larger than a deflection angle of the ribbon beam deflected by the energy separation electromagnet.

16. The ion implanter as claimed to claim 11, wherein the controller controls the mass analyzing electromagnet to deflect the ribbon beam and the energy separation electromagnet to deflect the ribbon beam such that a bend radius of the ribbon beam deflected by the mass analyzing electromagnet is smaller than a bend radius of the ribbon beam deflected by the energy separation electromagnet.

17. An ion implanter comprising:
an ion source that extracts a ribbon beam;
a mass analyzing electromagnet;
a mass resolution slit;
a corrector array;
an accelerator/decelerator tube;
an energy separation electromagnet;
a process chamber; and
a controller that controls the ion source, the mass analyzing electromagnet, the mass resolution slit, the corrector array, the accelerator/decelerator tube, and the energy separation electromagnet,
wherein the ribbon beam that is extracted passes in a traveling direction through the mass analyzing electromagnet, the mass resolution slit, the corrector array, the accelerator/decelerator tube, and the energy separation electromagnet to the process chamber,
wherein the controller controls the corrector array to adjust a beam current density distribution in a length direction of the ribbon beam, and
wherein the controller controls the mass analyzing electromagnet and the energy separation electromagnet such that deflection directions of the ribbon beam by the mass analyzing electromagnet and the energy separation electromagnet are opposite to each other with respect to the traveling direction of the ribbon beam.

18. The ion implanter as claimed in claim 17, wherein the corrector array comprises a plurality of electrodes that are arranged on opposite sides of the corrector array along the length direction of the ribbon beam,
wherein a number of electrodes on a first side of the corrector array is the same as a number of electrodes on a second side of the corrector array such that the plurality of electrodes form a plurality of pairs of electrodes facing each other with the ribbon beam passing between the plurality of pairs of electrodes, and
wherein a surface of each electrode on the first side that faces the second side is curved, and a surface of each electrode on the second side that faces the first side is curved.

19. The ion implanter as recited in claim 17, wherein a fringe magnetic field of the mass analyzing electromagnet is canceled out by a fringe magnetic field of the energy separation electromagnet.

20. The ion implanter as recited in claim 17, wherein the ribbon beam is incident obliquely to an inlet portion of the mass analyzing electromagnet.
